(19) United States
(12) Patent Application Publication
(10) Pub. No.: US 2025/0140527 A1
(43) Pub. Date: May 1, 2025

(54) Radical Supply Device, Radical Processing Device, Radical Generation Method and Substrate Processing Method

(71) Applicant: Tokyo Electron Limited, Tokyo (JP)

(72) Inventors: Jun YAMAWAKU, Yamanashi (JP); Tatsuo MATSUDO, Yamanashi (JP)

(21) Appl. No.: 19/005,718

(22) Filed: Dec. 30, 2024

Related U.S. Application Data
(63) Continuation of application No. PCT/JP2023/024054, filed on Jun. 28, 2023.

(30) Foreign Application Priority Data
Jul. 13, 2022 (JP) 2022-112230

(51) Int. Cl. H01J 37/32; C23C 16/455; H01L 21/3205

(52) U.S. Cl. CPC H01J 37/3244; C23C 16/45544; H01J 37/3211; H01J 2237/332; H01L 21/32051

(57) ABSTRACT

A radical supply apparatus for supplying radicals of a processing gas for processing a substrate comprises a housing divided into a radical generation space and a power supply space, a power supply coil provided in the power supply space, a catalyst coil that is disposed in the radical generation space at a position facing the power supply coil and configured to act as a metal catalyst when heated by non-contact power supply from the power supply coil, and a catalyst placing table disposed in the radical generation space, on which the catalyst coil is placed, and having a regulation member configured to regulate displacement of the catalyst coil, which is thermally expanded by heating, from the position facing the power supply coil. The radicals of the processing gas are generated by contacting the processing gas with the heated catalyst coil, and are supplied to a space for processing the substrate.

### CROSS-REFERENCE TO RELATED APPLICATIONS

This application is a bypass continuation application of International Application No. PCT/JP2023/024054 having an international filing date of Jun. 28, 2023 and designating the United States, the International Application being based upon and claiming the benefit of priority from Japanese Patent Application No. 2022-112230 filed on Jul. 13, 2022, the entire contents of which are incorporated herein by reference.

### TECHNICAL FIELD

The present disclosure relates to a radical supply apparatus, a radical processing apparatus, a method for generating radicals, and a method for processing a substrate.

### BACKGROUND

In a semiconductor device manufacturing process, a method for performing, e.g., film formation, on a semiconductor wafer (hereinafter referred to as “wafer”) as a substrate using a raw material gas and a reactive gas generated by catalytic action is known. For example, Japanese Laid-open Patent Publication No. 2008-227033 discloses a substrate processing apparatus including a processing chamber where a wafer is disposed, a processing gas supply source that supplies a processing gas such as hydrogen or the like into the processing chamber, and a catalyst heat generating member such as tungsten (W) that generates heat by power supply. Further, Japanese Laid-open Patent Publication No. 2008-227033 discloses that a processing gas is brought into contact with a high-temperature catalyst heat generating member to generate radicals, and the radicals are used to perform ashing or other processing on the substrate.

### SUMMARY

The present disclosure provides a technique capable of supplying radicals of a processing gas at a high concentration.

According to present disclosure, a radical supply apparatus for supplying radicals of a processing gas for processing a substrate comprises:
a housing divided into a radical generation space and a power supply space by a partition member configured to transmit electromagnetic waves;
a power supply coil provided in the power supply space, one end of which is connected to a high-frequency power supply and the other end of which is grounded or grounded via a capacitor;
a processing gas supply mechanism configured to supply the processing gas to the radical generation space;
a catalyst coil that is disposed in the radical generation space at a position facing the power supply coil and configured to act as a metal catalyst when heated by non-contact power supply from the power supply coil; and
a catalyst placing table disposed in the radical generation space, on which the catalyst coil is placed, and having a regulation member configured to regulate displacement of the catalyst coil, which is thermally expanded by heating, from the position facing the power supply coil,
wherein radicals of the processing gas are generated by contacting the processing gas with the heated catalyst coil, and are supplied to a space for processing the substrate.

### BRIEF DESCRIPTION OF THE DRAWINGS

FIG. 1 is a longitudinal side view of a radical processing apparatus according to a first embodiment of the present disclosure.

FIG. 2 shows an equivalent circuit of a power supply coil and a catalyst coil in the case of supplying a power to the radical processing apparatus.

FIG. 3A is a plan view of a catalyst placing table of the radical processing apparatus, and FIG. 3B is a cross-sectional view taken along a line IIIB-IIIB in FIG. 3A.

FIG. 4 is a perspective view showing an internal structure of a gas distribution plate of the radical processing apparatus.

FIGS. 5A and 5B show examples of a cross-sectional shape of the catalyst coil of the radical processing apparatus.

FIG. 6A is a first diagram showing an operation of the radical processing apparatus during substrate processing.

FIG. 6B is a second diagram showing the operation thereof during the substrate processing.

FIG. 6C is a third diagram showing the operation thereof during the substrate processing.

FIG. 6D is a fourth diagram showing the operation thereof during the substrate processing.

FIG. 7 is a longitudinal side view of a radical processing apparatus including a tubular catalyst coil.

FIG. 8 is a perspective view of the tubular catalyst coil and the catalyst placing table.

FIG. 9 is a plan view of the tubular catalyst coil.

FIG. 10 is an enlarged plan view of the catalyst coil having pins.

FIG. 11 is an enlarged longitudinal side view of the catalyst coil having the pins.

FIG. 12 is a longitudinal side view of a radical processing apparatus according to a second embodiment.

FIG. 13 is an enlarged longitudinal side view of the radical processing apparatus according to the second embodiment.

FIG. 14 is a longitudinal side view of a radical processing apparatus according to a third embodiment.

FIG. 15 is a longitudinal side view of a radical processing apparatus according to a fourth embodiment.

FIG. 16 is a longitudinal side view of a radical processing apparatus according to a fifth embodiment.

### DETAILED DESCRIPTION

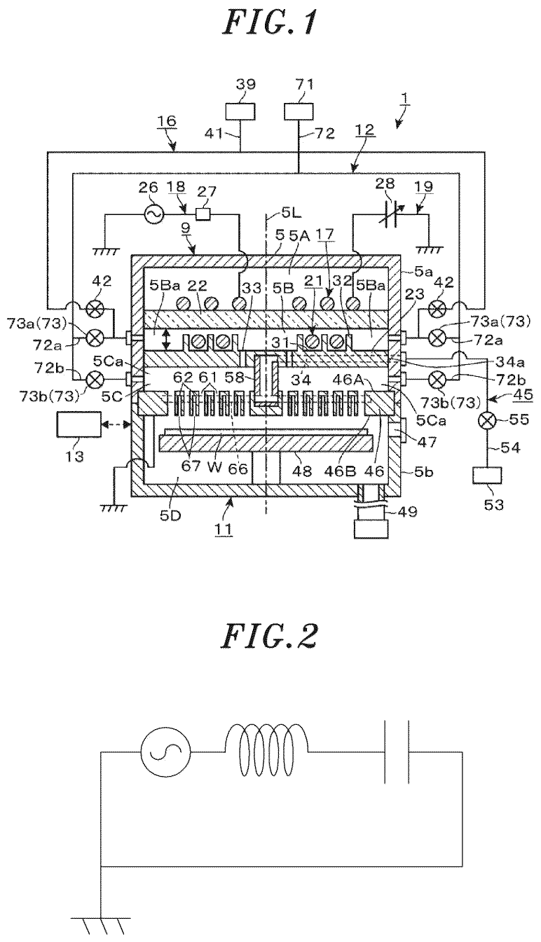

Hereinafter, a radical processing apparatus 1 according to an embodiment of the present disclosure will be described with reference to FIGS. 1 to 16.

### First Embodiment

The radical processing apparatus 1 of the present disclosure is configured as a device for performing film formation for forming a film on a substrate. The film formation is, e.g., atomic layer deposition (ALD), which is film formation on a substrate by repeatedly supplying a raw material gas, a reactive gas, and a purge gas in a predetermined order to a processing chamber where a substrate W is disposed. The radical processing apparatus 1 includes a housing 5 formed by assembling an upper housing 5a and a lower housing 5b that is a processing chamber. The housing 5 is made of a conductive material, specifically, aluminum having an anodically oxidized inner wall surface, and has a cylindrical shape, for example.

The housing 5 includes a plurality of spaces serving as channels for various gases. Specifically, the upper housing 5a includes a power supply space 5A, a radical generation space 5B for generating radicals of the processing gas, and a radical supply space 5C for supplying the generated radicals. The lower housing 5b includes a processing space 5D to which radicals are supplied. The power supply space 5A, the radical generation space 5B, the radical supply space 5C, and the processing space 5D are sequentially laminated downward, for example. The centers of the power supply space 5A, the radical generation space 5B, the radical supply space 5C, and the processing space 5D are located on a central axis 5L extending in the vertical direction of the housing 5, for example.

The radical processing apparatus 1 includes a radical supply mechanism 9, a substrate processing mechanism 11, a purge gas supply mechanism 12, and a controller 13. The radical supply mechanism 9 is mainly disposed in the upper housing 5a, and generates radicals of a processing gas, which is, e.g., a reactive gas, and supplies the radicals of the processing gas to the substrate processing mechanism 11. Hereinafter, the radicals of the processing gas may be simply referred to as “radicals.” The radical supply mechanism 9 includes a configuration of a radical supply apparatus that generates and supplies radicals, and the radical processing apparatus 1 is integrated with the radical supply apparatus. The substrate processing mechanism 11 is mainly disposed in the lower housing 5b in which the substrate W is disposed, and processes the substrate using radicals generated by the radical supply mechanism 9 and a raw material gas, for example. The controller 13 is electrically connected to the configuration in the radical processing apparatus 1 and performs two-way communication, thereby controlling the configuration in the radical processing apparatus 1.

The radical supply mechanism 9 includes a processing gas supply mechanism 16 that supplies a processing gas into the radical generation space 5B, a power supply coil 17 disposed in the power supply space 5A, a high-frequency power supply circuit 18 and a ground circuit 19 connected to the power supply coil 17, a catalyst coil 21 that is disposed in the radical generation space 5B while being separated from the power supply coil 17 and receives a power from the power supply coil 17 in a non-contact manner, a partition member 22 that is disposed between the catalyst coil 21 and the power supply coil 17 and transmits electromagnetic waves, and a catalyst placing table 23 having a regulation member that regulates the displacement of the catalyst coil 21.

The partition member 22 and the catalyst placing table 23 are formed as plate-shaped members, and are arranged in that order from the top with a gap therebetween. The partition member 22 and the catalyst placing table 23 divide the inside of the upper housing 5a into the power supply space 5A, the radical generation space 5B, and the radical supply space 5C. The partition member 22 and the catalyst placing table 23 area formed in disc shapes having substantially the same area, for example, and the centers thereof are located on the central axis 5L of the housing 5, for example. The power supply space 5A and the radical generation space 5B are separated by the partition member 22 and do not communicate with each other. The partition member 22 is made of a dielectric material such as quartz or the like. The power supply coil 17 is disposed on the upper surface of the partition member 22.

The power supply coil 17 and the catalyst coil 21 are coils formed by winding a wire in a spiral shape. Specifically, they are coils formed in a planar shape by winding a wire concentrically in a plane, that is, planar coils. The power supply coil 17 and the catalyst coil 21 are arranged such that the central axis of each wire is aligned with the central axis 5L of the housing 5, for example.

The power supply coil 17 and the catalyst coil 21 are arranged substantially in parallel to face each other horizontally toward a surface perpendicular to the direction of the central axis described above. Therefore, the catalyst coil 21 is disposed directly below the power supply coil 17. Further, central spaces where no wire is provided are formed at the inner sides of the inner ends of the wires of the power supply coil 17 and the catalyst coil 21.

The catalyst coil 21 is disposed on the upper surface of the catalyst placing table 23. The wire of the catalyst coil 21 has open ends at the inner end on the winding central axis side and the outer end on the opposite side, and is not fixed on both sides. The catalyst coil 21 contains at least one of platinum (Pt), rhenium (Re), iridium (Ir), or tungsten (W), and acts as a metal catalyst when heated. Specifically, the catalyst coil 21 is preferably tungsten or an alloy containing tungsten, which is stable even at a high temperature and has a high radical generation density. The total length of the winding of the catalyst coil 21 corresponds to a value obtained by multiplying a half of the length of the wavelength of the power supplied by the high-frequency power supply circuit 18 by a wavelength shortening ratio. The wavelength shortening ratio is, e.g., 0.5 to 1, and specifically, preferably 0.6 to 0.7.

The power supply coil 17 is placed on the upper surface of the partition member 22. The inner end on the winding central axis side of the wire of the power supply coil 17 is connected to, e.g., the high-frequency power supply circuit 18, and the outer end opposite to the inner end is connected to a ground circuit 19. Further, the outer end of the power supply coil 17 may be directly grounded without passing through the ground circuit 19.

The high-frequency power supply circuit 18 has one end that is grounded and the other end connected to the inner end of the power supply coil 17, and includes a high-frequency power supply 26 and a variable capacitor 27. The high-frequency power supply circuit 18 connects the high-frequency power supply 26 provided at one end in series with the variable capacitor 27 provided at the other end. The frequency of the power supplied by the high-frequency power supply 26 can be, e.g., 13.56 megahertz (MHz) within a range of 450 kilohertz (KHz) to 40 megahertz (MHz). The variable capacitor 27, which is, e.g., a high-frequency matching device, efficiently supply a power by suppressing reflected waves by performing impedance matching while changing a capacitance. The ground circuit 19 includes a variable capacitor 28 of which one end is connected to the power supply coil 17 and the other end is grounded.

With the above configuration, when a power is supplied from the high-frequency power supply circuit 18 to the power supply coil 17, the catalyst coil 21 receives the power from the power supply coil 17 in a non-contact manner. In this case, specifically, the power supply coil 17 and the catalyst coil 21 cause electromagnetic field resonance, so that a large amount of power is supplied to the catalyst coil 21. As shown in FIG. 2, the equivalent circuit of the power supply coil 17 and the catalyst coil 21 in this case is an LC resonant circuit in which a high-frequency power supply that supply a large amount of power, a coil, and a capacitor are connected in series and are grounded. The catalyst coil 21 operates as a dipole antenna with open ends on both sides. The dipole antenna that operates as described above resonates to generate a voltage standing wave that is maximum at the open end and a current standing wave that is maximum at the center. Therefore, the dipole antenna efficiently reduces reflected waves when viewed from the high-frequency power supply (the power supply coil 17) of the dipole antenna, and thus can efficiently supply a large amount of power. The catalyst coil 21 to which a large amount of power is supplied reaches a high temperature of 1000° C. or higher, for example, due to resistance heating. At a set temperature of 1000° C. or higher, the catalyst coil 21 efficiently acts as a metal catalyst, and efficiently converts the processing gas that is brought into contact with the catalyst coil 21 into radicals.

As shown in FIG. 5A, the cross-section of the winding of the catalyst coil 21 of the radical processing apparatus 1 may have a circular shape, for example. Alternatively, as shown in FIG. 5B, it may have a quadrilateral shape. In particular, when the cross-section of the winding of the catalyst coil 21 has a quadrilateral shape, the surface area of the catalyst coil 21 is increased, so that the contact area of the processing gas can be increased. Accordingly, radicals can be generated efficiently.

The catalyst placing table 23 is a support plate that supports the catalyst coil 21, and is made of a heat-resistant material such as quartz, ceramic, or the like. The catalyst placing table 23 has a support surface 31 that supports the catalyst coil 21, a protruding wall portion 32 that is a regulation member that regulates the catalyst coil 21, radical supply holes 33 that are through-holes that connect the radical generation space 5B and the radical supply space 5C, and a raw material gas channel 34 that is a channel for a raw material gas. In this example, the upper surface of the support plate that partitions the radical generation space 5B and the radical supply space 5C serves as the catalyst placing table 23 for the catalyst coil 21. However, the configuration of the catalyst placing table 23 is not limited to this example. For example, a support pillar may be provided at the center of the upper surface of the support plate, and the catalyst placing table 23 may be disposed on the upper end of the support pillar.

The protruding wall portion 32 and the support surface 31 of the catalyst placing table 23 are disposed, e.g., in the area facing the power supply coil 17 on the upper surface side of the catalyst placing table 23, i.e., in the area directly below the power supply coil 17.

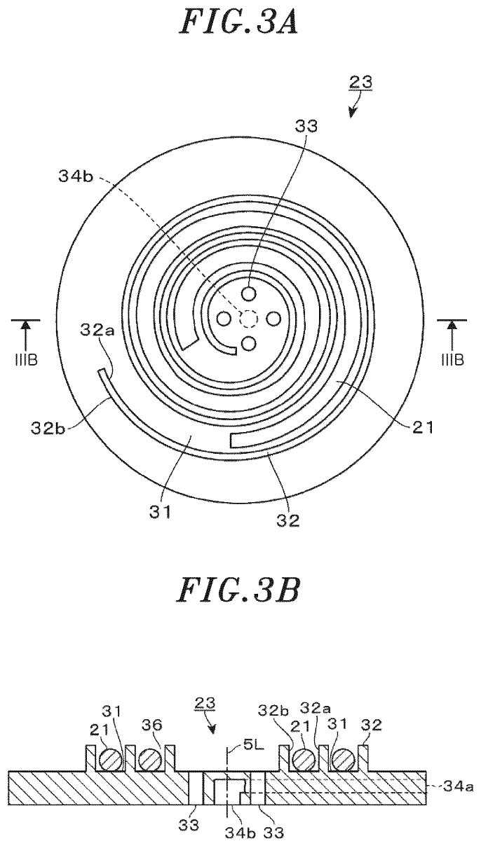

Further, the support surface 31 of the catalyst placing table 23 supports the spiral-shaped bottom surface of the catalyst coil 21. As shown in FIGS. 3A and 3B, the support surface 31 of the catalyst placing table 23 extends along the winding direction of the wire of the catalyst coil 21 on the spiral-shaped surface included in the upper surface of the catalyst placing table 23, for example. The support surface 31 is a surface larger than the bottom surface of the catalyst coil 21, and includes the area directly below the bottom surface of the catalyst coil 21.

The protruding wall portion 32 of the catalyst placing table 23 is a wall protruding from the support surface 31. As shown in FIG. 3A, the protruding wall portion 32 extends in a spiral shape along the winding direction of the wire of the catalyst coil 21 and the extension direction of the support surface 31 in plan view. As shown in FIG. 3B, when viewed in a vertical cross section intersecting the winding direction of the catalyst coil 21, the protruding wall portion 32 has an inner surface 32a and an outer surface 32b that are approximately parallel to each other. When viewed along the winding direction of the catalyst coil 21, the length of the protruding wall portion 32 is greater than the total length of the wire of the catalyst coil 21, for example. The length of the protruding wall portion 32 in the direction of the winding central axis of the catalyst coil 21, that is, the length in the vertical direction, is greater than or equal to the length of the catalyst coil 21 in the vertical direction, for example.

As shown in FIG. 3B, the catalyst coil 21 is disposed in a recess 36, which is a spiral space surrounded by the inner surface 32a and the outer surface 32b of the protruding wall portion 32 and the support surface 31. A sufficient gap that allow inflow of the processing gas is formed between the inner surface 32a or the outer surface 32b of the protruding wall portion 32 and the side surface of the catalyst coil 21. Further, the protruding wall portion 32 regulates the movement of the catalyst coil 21, which expands and contracts due to temperature changes, and prevents the catalyst coil 21 from displacing from the position facing the power supply coil 17. The radical supply holes 33 are formed to extend in the thickness direction of the catalyst placing table 23, which is the support plate, and are opened to the upper and bottom surfaces of the catalyst placing table 23. In the example shown in FIG. 3A, four radical supply holes 33 are formed to be closer to the center side of the catalyst placing table 23 than the protruding wall portion 32. In this regard, the radical supply holes 33 are not limited to the example shown in FIG. 3A, and one or more radical supply holes 33 may be formed in the catalyst placing table 23.

An example of setting the distance between the catalyst placing table 23 and the partition member 22 described above will be described in detail. The distance between the upper end of the protruding wall portion 32 and the bottom surface of the partition member 22 is set to be smaller than the distance between the upper surface of the main body of the catalyst placing table 23 and the bottom surface of the partition member 22. The distance (hereinafter, also referred to as “gap”) between the upper end of the catalyst coil 21 supported by the catalyst placing table 23 and the bottom surface of the partition member 22 is set to be substantially the same as the distance between the upper end of the protruding wall portion 32 and the partition member 22. A desired range of the size of the gap varies depending on conditions for generating radicals. For example, as will be described later, when radicals are generated by producing plasma of a processing gas in addition to the action of a metal catalyst, the gap is preferably set to be larger than 30 mm. Alternatively, when radicals are generated mainly by the action of the metal catalyst, the gap is preferably set to 30 mm or less.

The raw material gas channel 34 of the catalyst placing table 23 is a tubular space that is formed in the catalyst placing table 23 to extend along the radial direction of the catalyst placing table 23. One end of the raw material gas channel 34 of the catalyst placing table 23 is connected to a side opening 34a that is opened on the side surface of the catalyst placing table 23. Further, the downward extension direction of the other end of the raw material gas channel 34 changes at the central portion of the catalyst placing table 23. The downstream end of the raw material gas channel 34 forms a lower opening 34b that is opened at the central portion of the bottom surface of the catalyst placing table 23. As shown in FIGS. 3A and 3B, the lower opening 34b of the raw material gas channel 34 is disposed on the center side of the radical supply holes 33 described above, specifically on the central axis 5L of the housing 5. In the catalyst placing table 23, the raw material gas channel 34 and the radical supply holes 33 are formed separately from each other, and are not connected to each other.

As shown in FIG. 1, the processing gas supply mechanism 16 includes a processing gas supply source 39, a processing gas line 41 that connects the processing gas supply source 39 and the radical generation space 5B, and processing gas valves 42 disposed on the processing gas line 41. The processing gas line 41 is branched into two lines at the outlet side of the processing gas supply source 39 to form branch lines. The two branch lines are connected to the radical generation space 5B through two through-holes facing each other on the side portion of the upper housing 5a. Accordingly, the processing gas line 41 introduces the processing gas into the areas of two opposing ends 5Ba of the radical generation space 5B.

The processing gas valves 42 are disposed at the downstream ends of the two branch lines of the processing gas line 41, respectively. The opening and closing of the processing gas valves 42 are controlled by the controller 13, so that the flow of the processing gas into the radical generation space 5B is controlled. The processing gas may be, for example, hydrogen (H₂) gas, oxygen (O₂) gas, difluorocarbon cation (CF₂) gas, or ammonia (NH₃) gas. For example, when tungsten hexafluoride (WF₆) is supplied as a raw material gas, H₂ gas that reduces WF₆ is supplied as the processing gas.

The high-frequency power supply circuit 18, the ground circuit 19, and the processing gas supply mechanism 16 are electrically connected to the controller 13 to be described later. The controller 13 controls the operation and stop of the high-frequency power supply 26 and the variable capacitor 27 of the high-frequency power supply circuit 18, and controls the opening and closing of the processing gas valves 42 of the processing gas supply mechanism 16. After the catalyst coil 21 is sufficiently heated by the operation of the high-frequency power supply circuit 18 and the ground circuit 19, the radical supply mechanism 9 distributes the processing gas from the processing gas supply mechanism 16 to the radical generation space 5B of the upper housing 5a through the processing gas line 41. The processing gas that is brought into contact with the heated catalyst coil 21 becomes radicals, and the radicals flow into the radical supply space 5C via the radical supply holes 33. In this manner, the radical supply mechanism 9 supplies radicals to the processing space 5D of the substrate processing mechanism 11 on the downstream side of the radical supply space 5C. Further, the processing gas that is not brought into contact with the heated catalyst coil 21 does not become radicals, so that a processing gas that has not been radicalized flows in the processing space 5D, in addition to the radicals. Hereinafter, “processing gas that has not been radicalized” may also be referred to as “non-radicalized gas.”

The substrate processing mechanism 11 of the radical processing apparatus 1 includes a raw material gas supply mechanism 45 for supplying a raw material gas to the processing space 5D, a gas distribution plate 46 for circulating the processing gas and the raw material gas in the processing space 5D, a loading/unloading port 47 penetrating through the side portion of the lower housing 5b and configured to load/unload the substrate W, a substrate placing table 48 on which the loaded substrate W is placed, and an exhaust line 49 penetrating through the bottom portion of the lower housing 5b and configured to discharge a gas in the processing space 5D.

The loading/unloading port 47 is disposed to penetrate through the side portion of the lower housing 5b, and connects the processing space 5D of the lower housing 5b and an external space, e.g., a vacuum transfer chamber (not shown) where the substrate W is transferred so that the substrate W can pass therethrough. The loading/unloading port 47 is provided with a gate valve that is controlled by the controller 13 to be opened and closed the loading/unloading port 47. In response to an instruction from the controller 13, the gate valve opens the loading/unloading port 47 when the substrate W is loaded/unloaded, and closes the loading/unloading port 47 during the substrate processing.

The substrate placing table 48 is disposed in the processing space 5D of the lower housing 5b, and is supported from the bottom surface side of the lower housing 5b. The central axis of the substrate placing table 48 is disposed to be substantially the same as the central axis 5L of the housing 5, and the substrate W is placed with the center of the substrate W positioned on the central axis of the substrate placing table 48. The substrate placing table 48 faces the gas distribution plate 46 on the central axis 5L of the housing 5, and the placed substrate W is disposed directly below the gas distribution plate 46.

The raw material gas supply mechanism 45 of the substrate processing mechanism 11 has, e.g., a raw material gas supply source 53, a raw material gas line 54 that connects the raw material gas supply source 53 and the raw material gas channel 34 on the catalyst placing table 23 side, and a raw material gas valve 55 disposed on the raw material gas line 54. The raw material gas line 54 is connected to the side opening 34a of the raw material gas channel 34 of the catalyst placing table 23 via a through-hole on the side portion of the upper housing 5a, for example. Accordingly, the raw material gas line 54 introduces the raw material gas supplied from the raw material gas supply source 53 to the raw material gas channel 34 of the catalyst placing table 23. The raw material gas valve 55 controls the flow of the raw material gas to the raw material gas channel 34 of the catalyst placing table 23 by the opening/closing control of the controller 13. For example, in the case of forming a tungsten film on the substrate W, the raw material gas is, e.g., a gas containing tungsten hexafluoride (WF₆) as a film raw material.

The gas distribution plate 46 is provided to divide the space below the catalyst placing table 23 in the housing 5 into the radical supply space 5C and the processing space 5D. Further, the gas distribution plate 46 is disposed below the catalyst placing table 23, and thus is provided to partition the radical generation space 5B and the processing space 5D. The gas distribution plate 46 has a disc shape, for example, and has an area that is substantially equal to the area of the partition member 22 and the catalyst placing table 23. The center of the gas distribution plate 46 is located on the central axis 5L of the housing 5, for example. The gas distribution plate 46 is interposed between the edges of the upper housing 5a and the lower housing 5b of the housing 5 that are fitted together, and is grounded. Therefore, the inner spaces of the upper housing 5a and the lower housing 5b are individually shielded. In addition, the gas distribution plate 46 is provided with a connection line 58 that connects the gas distribution plate 46 and the catalyst placing table 23.

The gas distribution plate 46 is provided with a plurality of radical channels 61 and a plurality of raw material gas channels 62. The plurality of radical channels 61 and the plurality of raw material gas channels 62 are provided in the area directly above the substrate W placed on the substrate placing table 48. The radical channels 61 penetrate from an upper surface 46A to a bottom surface 46B of the gas distribution plate 46, thereby connecting the radical supply space 5C and the processing space 5D. Further, the radical channels 61 are also connected to the radical generation space 5B via the radical supply holes 33 of the catalyst placing table 23. The downstream ends of the plurality of radical channels 61 are opened while being substantially uniformly distributed in the area directly above the substrate W except the central area of the gas distribution plate 46 in plan view.

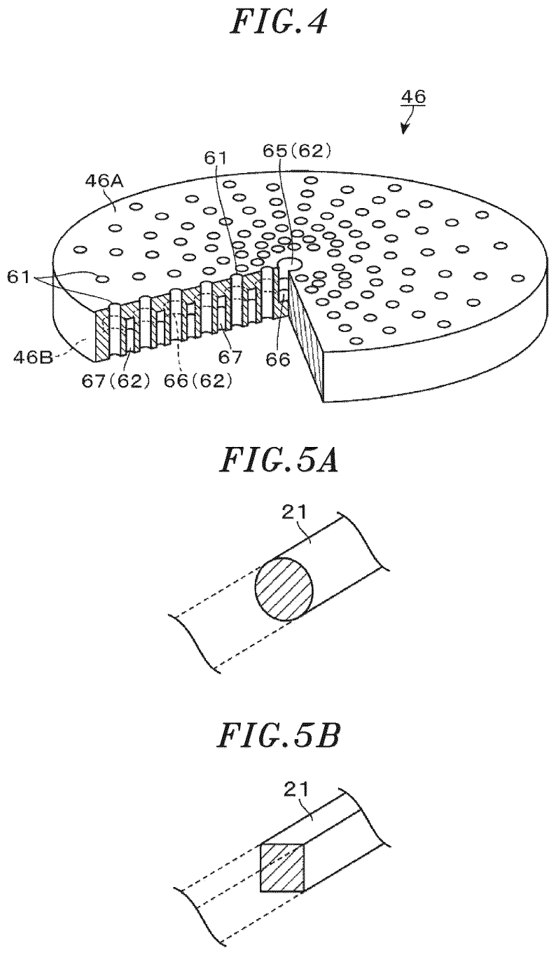

FIG. 4 is a perspective view showing the internal structure of the gas distribution plate 46 of the radical processing apparatus 1. The radical channels 61 and the raw material gas channels 62 in FIG. 4 are partially omitted. As shown in FIGS. 1 and 4, the raw material gas channel 62 includes a connection passage 65 constituting the upstream end of the raw material gas channel 62, a distribution passage 66 disposed on the downstream side of the connection passage 65, and a plurality of downstream ends 67 branched from the distribution passage 66. The connection passage 65 extends vertically along the central axis of the gas distribution plate 46, and is opened at the center of the upper surface 46A of the gas distribution plate 46. The downstream end of the connecting line 58 is connected to the connection passage 65, and the upstream end of the connection line 58 is connected to the lower opening 34b of the raw material gas channel 34 of the catalyst placing table 23. Accordingly, the raw material gas flows in the distribution passage 66 via the raw material gas channel 34 of the catalyst placing table 23, the connection line 58, and the connection passage 65.

The distribution passage 66 of the raw material gas channel 62 is connected to the downstream end of the connection passage 65, and is formed in the gas distribution plate 46 to be widened in a substantially planar shape or substantially radial shape from the center in the region directly above the substrate W of the gas distribution plate 46. Further, the distribution passage 66 is separated from the above-described plurality of radical channels 61 in a direction intersecting the vertical direction, and is disposed to surround the side surfaces of the radical channels 61.

The plurality of downstream ends 67 of the raw material gas channel 62 extend from a part of the bottom surface of the distribution passage 66 toward the bottom surface 46B of the gas distribution plate 46, and are opened on the bottom surface 46B of the gas distribution plate 46. The plurality of downstream ends 67 are substantially uniformly distributed in the area directly above the substrate W of the gas distribution plate 46 in plan view.

Further, the plurality of downstream ends 67 of the raw material gas channels 62 are separated from the radical channels 61 in a direction intersecting the vertical direction, and are not connected to any of the radical channels 61 in the gas distribution plate 46. The downstream ends 67 of the raw material gas channels 62 are disposed in the gap between two adjacent radical channels 61, for example. With the above-described arrangement of the radical channels 61 and the raw material gas channels 62, the radical channels 61 and the raw material gas channels 62 are disposed substantially uniformly in the area directly above the substrate W on the bottom surface 46B of the gas distribution plate 46, so that the radicals and the raw material gas are uniformly brought into contact with the upper surface of the substrate W disposed on the substrate placing table 48. In this manner, the raw material gas channels 62 and the radical channels 61 are isolated from each other in the surface of the gas distribution plate 46. With this configuration, the radicals or the raw material gas can be supplied independently toward the processing space 5D.

As shown in FIG. 1, the purge gas supply mechanism 12 of the radical processing apparatus 1 includes, e.g., a purge gas supply source 71, a purge line 72 that connects the purge gas supply source 71 to the radical generation space 5B or the radical supply space 5C, and a purge valve 73 disposed on the purge line 72. The purge line 72 is branched into two on the outlet side of the purge gas supply source 71. Each of the branched lines is further branched into two on the downstream side to form a first branch line 72a connected to the radical generation space 5B and a second branch line 72b connected to the radical supply space 5C.

The downstream side of the first branch line 72a joins with the branch line of the processing gas line 41. The first branch line 72a is connected to the radical generation space 5B through two opposing through-holes on the side portion of the upper housing 5a. On the other hand, the second branch line 72b is connected to the radical supply space 5C through two opposing through-holes on the side portion of the upper housing 5a. Accordingly, the purge line 72 introduces a purge gas into the area of the two opposing ends 5Ba of the radical generation space 5B, and introduces a purge gas into the area of the two opposing ends 5Ca of the radical supply space 5C.

The purge valve 73 includes a first purge valve 73a disposed on each of the two first branch lines 72a, and a second purge valve 73b disposed on each of the two second branch lines 72b. The first purge valve 73a controls the flow of the purge gas into the radical generation space 5B by the opening/closing control of the controller 13. Therefore, at least one of the processing gas and the purge gas is appropriately supplied to the radical generation space 5B. The second purge valve 73b controls the flow of purge gas into the radical supply space 5C by the opening/closing control of the controller 13. In this manner, the purge gas is also directly supplied to the radical supply space 5C. The purge gas is, e.g., nitrogen (N₂) gas, argon (Ar) gas, or the like.

The exhaust line 49 is disposed to penetrate through the bottom surface of the lower housing 5b, and a vacuum exhaust mechanism whose gas exhaust operation is controlled by the controller 13 is disposed on the downstream side of the exhaust line 49. The vacuum exhaust mechanism operates constantly during the substrate processing according to instructions from the controller 13, and adjusts a pressure in the processing space 5D to a preset value by a pressure control mechanism (not shown). For example, the pressure loss that occurs when the gas passes through the radical supply holes 33 of the catalyst placing table 23 and the pressure loss that occurs when the gas passes through the radical channels 61 of the gas distribution plate 46 are designed to a predetermined value. As a result, when the pressure in the processing space 5D is adjusted to a preset pressure by the pressure control mechanism, the pressure in the radical generation space 5B is also adjusted to a pressure corresponding thereto. Further, a desired range of the pressure in the radical generation space 5B changes depending on conditions for generating radicals. For example, as will be described later, when radicals are generated by producing plasma of the processing gas in addition to the action of the metal catalyst, the pressure in the radical generation space 5B is preferably adjusted to be lower than 133 Pa (1 torr). Alternatively, when radicals are generated mainly by the action of the metal catalyst, the pressure in the radical generation space 5B is preferably adjusted to be 133 Pa (1 torr) or higher.

The controller 13 is, e.g., a computer, and includes a data processing part including a program, a memory, and a central processing unit (CPU). The program includes commands that send control signals from the controller 13 to individual components of the radical processing apparatus 1 and cause the substrate processing to proceed. The program is stored in a storage part of a computer storage medium, such as a flexible disk, a compact disk, a hard disk, a magneto-optical (MO) disk, and is installed in the controller 13.

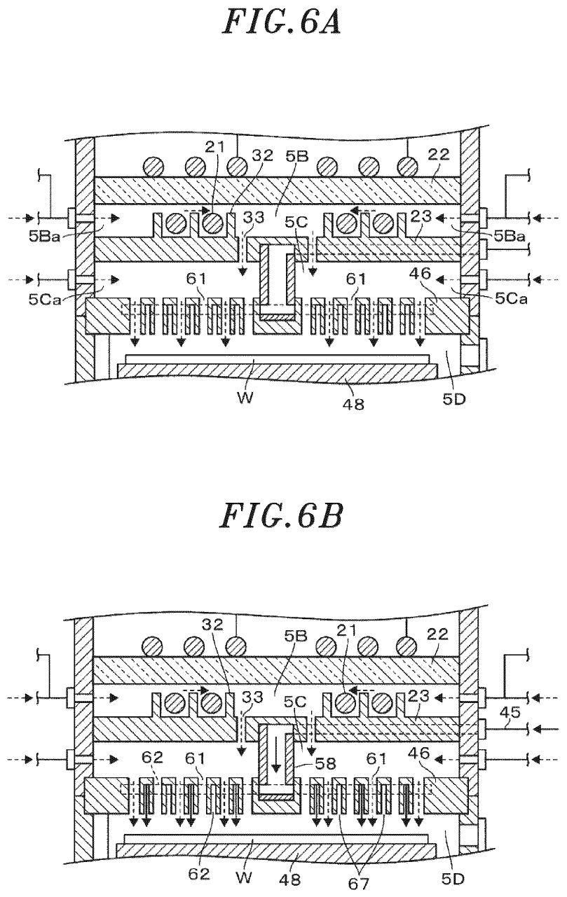

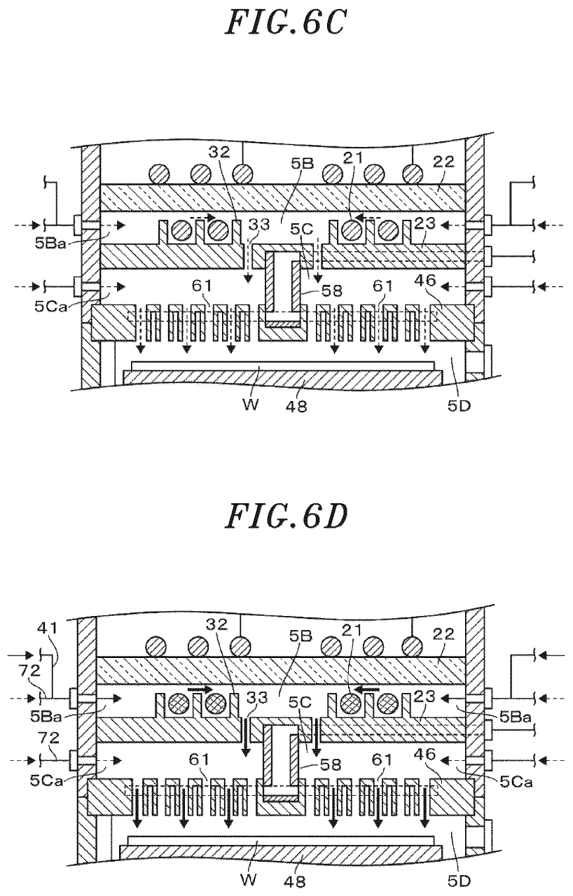

FIGS. 6A to 6D show the operations of the radical processing apparatus 1 during the substrate processing. The film formation for a substrate W, which is an example of the substrate processing of the radical processing apparatus 1 in the present embodiment, will be described using FIGS. 6A to 6D. In FIGS. 6A to 6D, the flow of a purge gas is indicated by dashed line arrows, the flow of a raw material gas, the flow of a processing gas alone, or the flow of a mixed gas of a purge gas and a processing gas is indicated by solid line arrows, and the flow of a mixed gas of radicals, a non-radicalized gas, and a purge gas is indicated by thick arrows. Further, in FIGS. 6A to 6C, the diagonal hatching in the catalyst coil 21 indicates that the catalyst coil 21 has not reached the set temperature at which the catalyst coil 21 acts as a metal catalyst. Further, in FIG. 6D, the lattice-shaped hatching in the catalyst coil 21 indicates that the catalyst coil 21 has reached the set temperature at which the catalyst coil 21 acts as a metal catalyst.

In the substrate processing, first, the substrate W is transferred from the outside into the radical processing apparatus 1 through the loading/unloading port 47, and then is placed at a predetermined position on the substrate placing table 48. All valves in the radical processing apparatus 1 are closed, and the space in the housing 5 is set as a closed space, for example. Next, the vacuum exhaust mechanism performs evacuation through the exhaust line, and the processing space 5D is adjusted to a preset pressure. In this case, the purge gas is supplied to the radical generation space 5B and the radical supply space 5C by the purge gas supply mechanism 12. As indicated by the dashed lines in FIG. 6A, the purge gas supplied to the radical generation space 5B and the radical supply space 5C flows in the radical generation space 5B, the radical supply space 5C, and the processing space 5D, and is exhausted from the exhaust line 49. Such operations of the vacuum exhaust mechanism and the purge gas supply mechanism 12 are performed continuously during the substrate processing, for example.

Next, a power is supplied to the power supply coil 17 by operating the high-frequency power supply circuit 18 and the ground circuit 19, thereby increasing the temperature of the catalyst coil 21. Then, as shown in FIG. 6B, the raw material gas is supplied by the raw material gas supply mechanism 45. The raw material gas flows into the processing space 5D through the raw material gas channel 34 of the catalyst placing table 23, the connection line 58, and the raw material gas channels 62. Since the plurality of downstream ends 67 of the raw material gas channels 62 are uniformly provided in the area directly above the substrate W on the gas distribution plate 46, the raw material gas flows uniformly toward the substrate W in the processing space 5D from the area directly above the substrate W. Then, the molecules of the raw material gas quickly reach the entire upper surface of the substrate W and are uniformly adsorbed on the entire upper surface of the substrate W.

The raw material gas channel is separated from the channel of the processing gas at the upstream of the gas distribution plate 46 and at the gas distribution plate 46, and the purge gas is discharged from the radical channels 61. Hence, the inflow of the raw material gas or the corrosive gas (hydrogen fluoride in the case of the reaction between WF₆ and hydrogen radicals) generated by the reaction between molecules contained in various gases supplied to the processing space 5D into the radical supply space 5C and the radical generation space 5B is suppressed. Accordingly, it is possible to suppress the corrosion of the catalyst coil 21 by the raw material gas or the corrosive gas, or the progress of the film formation reaction in the radical supply space 5C and the radical generation space 5B.

As shown in FIG. 6C, when the time required for the molecules of the raw material gas to be uniformly adsorbed on the entire upper surface of the substrate W elapses, the supply of the raw material gas by the raw material gas supply mechanism 45 is stopped. The supply of the purge gas continues, and the purge gas is exhausted from the processing space 5D together with the raw material gas remaining in the processing space 5D (see FIG. 6A).

Thereafter, when the time required for the remaining raw material gas to be completely discharged from the processing space 5D elapses and the temperature of the catalyst coil 21 increased to a set temperature of 1000° C. or higher, the processing gas is supplied to the radical generation space 5B by the processing gas supply mechanism 16, as shown in FIG. 6D. The mixed gas, which is a mixture of the processing gas and the purge gas obtained at the downstream end of the processing gas line 41, flows into the area of the two opposing ends 5Ba on the side portion of the radical generation space 5B. Then, the mixed gas flows from the two opposing ends 5Ba toward the central area of the radical generation space 5B that faces the radical supply holes 33, and spreads throughout the entire radical generation space 5B. When the mixed gas passes through the area where the catalyst coil 21 is located in the radical generation space 5B, the processing gas is brought into contact with the catalyst coil 21 and becomes radicals.

Specifically, when the processing gas flowing toward the central area of the radical generation space 5B passes through the narrow gap between the protruding wall portion 32 and the partition member 22, the processing gas passes through the plurality of wound wires of the catalyst coil 21 and flows toward the central area of the radical generation space 5B. In this case, a part of the processing gas flows into the recess 36 of the protruding wall portion 32, and is also brought into contact with the side surface of the catalyst coil 21. In this manner, the processing gas flows from the peripheral side of the catalyst coil 21 formed as a planar coil toward the central axis, and thus is repeatedly brought into contact with the catalyst coil 21, which increases the contact frequency. As a result, radicals can be generated at a high concentration in the radical generation space 5B. The mixed gas of the radicals generated at a high concentration, the non-radicalized gas that is not yet radicalized, and the purge gas join together in the central area of the radical generation space 5B and flow into the radical supply space 5C from the radical supply holes 33. Hereinafter, “mixed gas of radicals, non-radicalized gas, and purge gas” may also be referred to as “radical mixed gas.”

The radical supply mechanism 9 of the present embodiment can also generate high-concentration radicals in the radical generation space 5B by producing inductively coupled plasma (ICP) that converts a processing gas into plasma using a high-frequency power supplied from the power supply coil 17. In this case, it is preferable that the radical supply mechanism 9 sets a pressure in the radical generation space 5B to 133 Pa (1 Torr) or less and sets the distance between the catalyst coil 21 and the partition member 22 to 30 mm or more. Since, however, the plasma of the processing gas contains more ions compared to the case of radicalization by a metal catalyst, in addition to radicals, the substrate W may be damaged. Further, the deterioration of the catalyst coil 21 is also accelerated due to the contact of the plasma with the catalyst coil 21. Hence, when high-concentration radicals are obtained by combining the action of the metal catalyst of the catalyst coil 21 and the ICP plasma, it is necessary to consider the influence of ions and the deterioration of the catalyst coil 21.

Therefore, if it is desired to avoid the generation of ICP in the radical generation space 5B and suppress the generation of ions, the opposite condition may be set. In this case, it is preferable that the radical supply mechanism 9 sets a pressure in the radical generation space 5B to be higher than 133 Pa (1 torr) and the distance between the catalyst coil 21 and the partition member 22 to be less than 30 mm. Under such conditions, the influence of plasma on the catalyst coil 21 is reduced, so that the deterioration of the catalyst coil 21 is reduced and the lifetime is extended. In addition, the generation of high-energy ions is suppressed, so that the influence of ions on the substrate W is reduced and the substrate processing is stabilized.

The radical mixed gas containing the radicals generated in the radical generation space 5B as described above flows from the radical supply holes 33 to the central area of the radical supply space 5C. Then, it is mixed with the flow of the purge gas flowing from the two opposing ends 5Ba of the side portions of the radical supply space 5C toward the central region, and becomes a radical mixed gas having a substantially uniform concentration of radicals. The radical mixed gas having a substantially uniform concentration in the radical supply space 5C contains high-concentration radicals. Thus, when it is supplied from the radical channels 61 of the gas distribution plate 46 to the processing space 5D, the substrate processing is efficiently performed.

Specifically, the radical mixed gas supplied from the plurality of radical channels 61 of the gas distribution plate 46 flows into the processing space 5D, and then is supplied to the entire upper surface of the substrate W. Then, the radicals react with the raw material gas molecules absorbed on the substrate W, so that only the film-forming molecules remain. Accordingly, a single layer of film (e.g., a tungsten film) is formed on the entire upper surface of the substrate W.

Next, when the time required to form a single layer of film on the entire upper surface of the substrate W elapses, as shown in FIG. 6A, the supply of the processing gas by the processing gas supply mechanism 16 is stopped, and only the purge gas is supplied to the radical generation space 5B and the radical supply space 5C again. The supplied purge gas is exhausted from the processing space 5D together with the remaining radical mixed gas and radical bonding molecules. In this manner, a film of a desired thickness is formed on the substrate W by repeating the supply of the raw material gas (see FIG. 6B)→the supply of the purge gas (see FIG. 6C)→the supply of the radical mixed gas (see FIG. 6D)→the supply of the purge gas (see FIG. 6A). Then, the supply of gases other than the purge gas is stopped. Then, the substrate W on which the film is formed is unloaded in the reverse order of the loading operation, and a next substrate W stands by for loading. Further, the operation of the high-frequency power supply circuit 18 and the ground circuit 19 may be stopped, and the power supply to the power supply coil 17 may be continued. The catalyst coil 21 may be maintained at a high temperature until the next substrate W is loaded. As described above, the radical processing apparatus 1 efficiently processes a substrate using high-concentration radicals generated by the radical supply mechanism 9.

The catalyst coil 21, whose temperature changes greatly in the substrate processing as described above, expands and contracts in response to the increase and decrease of the temperature. The amount of expansion and contraction in the winding direction of the wire, i.e., in the longitudinal direction, increases from the intermediate portion of the wire of the catalyst coil 21 toward both ends thereof. When the substrate processing is repeated multiple times, the wire of the catalyst coil 21 expands and contracts repeatedly, and is likely to be displaced from the position facing the power supply coil 17. However, in the catalyst coil 21 of the present embodiment, at least a part of the wire is disposed to face the protruding wall portion 32, so that the displacement of the wire is regulated by the protruding wall portion 32. In this manner, the catalyst coil 21 is prevented from displacing from the position facing the power supply coil 17.

Further, at least a part of the wire of the catalyst coil 21 is disposed substantially parallel to the protruding wall portion 32 extending along the winding direction of the wire of the catalyst coil 21. Therefore, even if the wire expands and contracts, the catalyst coil 21 is unlikely to be displaced from the protruding wall portion 32 extending along the winding direction, and the displacement including rotation around the winding center axis is effectively suppressed. In the spiral-shaped protruding wall portion 32 of the present embodiment, which includes all the above-described configurations, the entire wire of the catalyst coil 21 extends along the winding direction, and faces the entire inner and outer surfaces of the wire of the catalyst coil 2. Accordingly, it is possible to reliably prevent the catalyst coil 21 from being displaced from the position facing the power supply coil 17. Further, the catalyst coil 21, whose displacement is regulated by the protruding wall portion 32, is not fixed to the catalyst placing table 23 with a part of the catalyst coil 21, such as an end portion or the like, as a fixed part, and thus is less susceptible to stress concentration on the fixed part and less susceptible to fatigue failure.

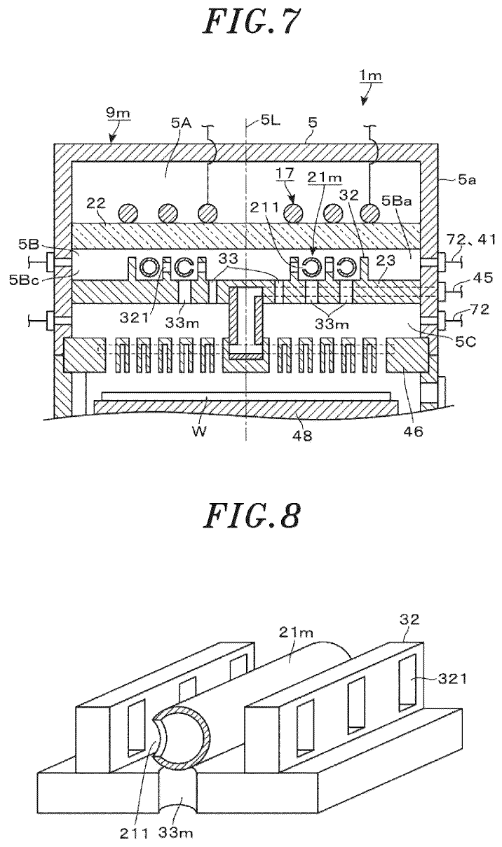

Hereinafter, variations of the radical supply mechanism 9 of the present disclosure will be described with reference to FIGS. 7 to 16. In FIGS. 7 to 16, like components as those the radical processing apparatus 1 according to the embodiment described using FIGS. 1 to 6 are denoted by like reference numerals as those in FIGS. 1 to 6.

### (Tubular Catalyst Coil)

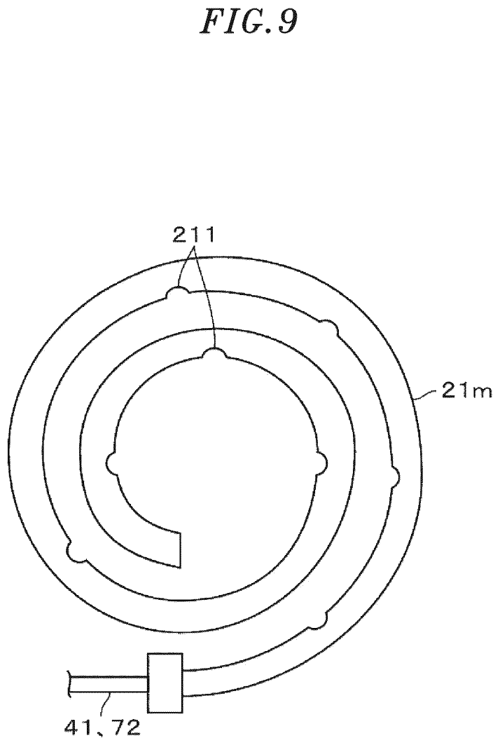

FIG. 7 shows an enlarged longitudinal side view of a radical processing apparatus 1m in which a tubular catalyst coil 21m is disposed in the radical generation space 5B of a radical supply mechanism 9m. FIG. 8 shows an enlarged perspective view of the tubular catalyst coil 21m and the catalyst placing table 23, and FIG. 9 shows a plan view of the tubular catalyst coil 21m. As shown in FIG. 9, the above-described processing gas line 41 and the purge line 72 are connected to the outer end of the tubular catalyst coil 21m. The processing gas supply mechanism 16 can supply a processing gas toward the inner space of the tubular catalyst coil 21m. Therefore, as shown in FIG. 7, in the radical generation space 5B where the tubular catalyst coil 21m is disposed, a processing gas is supplied into the tubular catalyst coil 21m, as well as to the outer surface of the catalyst coil 21m via the areas of the two opposing ends 5Ba.

As shown in FIGS. 8 and 9, a plurality of openings 211 are formed at intervals in the sidewall of the wire of the tubular catalyst coil 21m on the inner circumferential side, for example. Further, when the temperature of the tubular catalyst coil 21m is increased by non-contact power supply from the power supply coil 17 and a processing gas is supplied to the inner space thereof, the processing gas is brought into contact with the inner wall surface of the catalyst coil 21m and generates radicals. The radical mixed gas containing the generated radicals is discharged from the inner space to the radical generation space 5B through the plurality of openings 211. The radical mixed gas discharged from each opening 211 joins with the radical mixed gas flowing on the radical generation space 5B side. Further, the unreacted processing gas contained in the radical mixed gas is brought into contact with the outer wall surface of the catalyst coil 21m and generates radicals. In this manner, by using the tubular catalyst coil 21m, the contact area of the processing gas can be increased, and higher-concentration radicals can be generated.

FIGS. 7 and 8 also show an example in which a plurality of communication holes 321 are formed in the sidewall of the protruding wall portion 32 disposed along the catalyst coil 21m. By providing the communication holes 321, the flow in which the radical mixed gas passes through the protruding wall portion 32 and enters the area where an adjacent catalyst coil 21m is disposed is formed. As a result, the radical mixed gas is more likely to be repeatedly brought into contact with the outer wall surface of the catalyst coil 21m, and high-concentration radicals can be generated. In addition, FIGS. 7 and 8 show an example in which a plurality of radical supply holes 33m are formed in the catalyst placing table (the support plate) 23 disposed on the bottom surface of the area where the catalyst coil 21m fitted between the spiral protruding wall portions 32 is disposed. Since the radical supply holes 33m are also formed in the area where the catalyst coil 21m is disposed, the radical mixed gas containing high-concentration radicals can flow into the radical supply space 5C before the radicals are brought into contact with other members (e.g., the protruding wall portion 32, the catalyst placing table 23, and the bottom surface of the partition member 22) are deactivated. Further, the configuration in which the plurality of communication holes 321 are formed in the side surface of the protruding wall portion 32 or the configuration in which the plurality of radical supply holes 33m are formed in the catalyst placing table 23 is not necessarily provided in the radical generation space 5B where the tubular catalyst coil 21m is disposed. For example, such configurations may be provided in the radical supply space 5C of the radical processing apparatus 1 according to the first embodiment shown in FIG. 1.

### (Coil Having Pins)

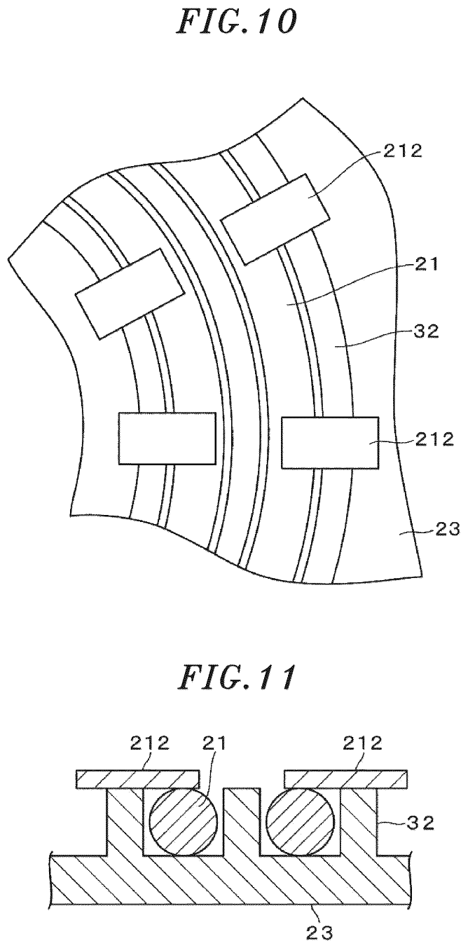

Next, FIG. 10 and FIG. 11 show a configuration in which a plurality of pins 212 acting as metal catalysts are provided on the outer surface, e.g., the upper surface, of the catalyst coil 21. FIG. 10 is an enlarged plan view of the catalyst coil 21 having the pins 212, and FIG. 11 is an enlarged longitudinal side view thereof. When the temperature of the catalyst coil 21 is increased by non-contact power supply from the power supply coil 17, the temperature of the pins 212 is increased by heat transfer from the main body of the catalyst coil 21. As a result, the pins 212 act as metal catalysts, and radicals can be generated from the processing gas in contact with the surfaces of the pins 212. By providing the pins 212, the area serving as a metal catalyst can be increased, and high-concentration radicals can be generated. Further, the configuration in which the pins 212 are disposed at the tubular catalyst coil 21m described using FIGS. 7 to 9 may also be adopted.

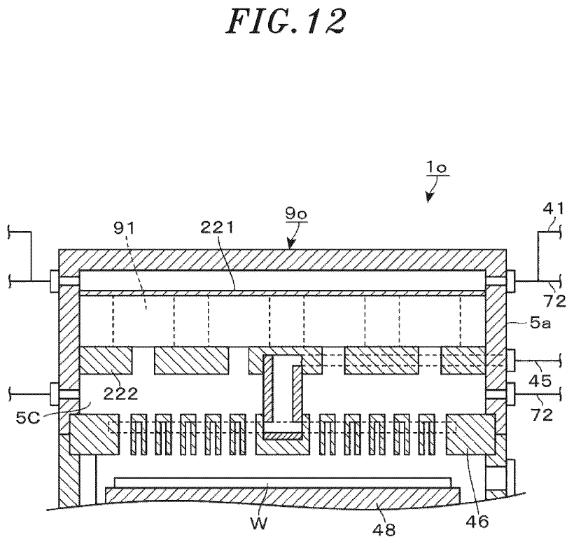

In each of the examples described above, the case where each of the power supply coil 17 and the catalyst coils 21 and 21m is configured as a planar coil has been described. On the other hand, the coil of which temperature can be increased by non-contact power supply is not limited to a planar coil. For example, the same effect can be obtained from a coil formed in a coaxial shape by arranging a wire in a helical shape, that is, a coaxial coil. In the following examples shown in FIGS. 12 to 16, an embodiment in which the technique of the present disclosure is applied to a coaxial coil will be described.

### Second Embodiment

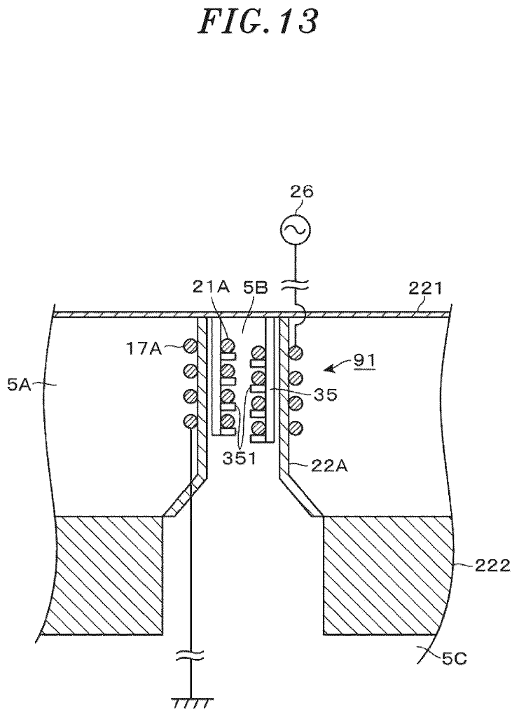

FIG. 12 shows an enlarged longitudinal side view of a radical processing apparatus 10 including a radical supply mechanism 90 according to a second embodiment. In the radical supply mechanism 90, a ceiling plate 221 and a support plate 222 are arranged parallel to each other with a vertical gap therebetween above the radical supply space 5C. In the space between the ceiling plate 221 and the support plate 222, a plurality of radical supply units 91 are arranged at horizontal gaps. FIG. 13 shows an enlarged vertical cross-sectional view of the radical supply unit 91. In the radical supply unit 91, a coaxial power supply coil 17A is disposed along the outer peripheral surface of a cylindrical partition member 22A formed as, e.g., a quartz tube, and a coaxial catalyst coil 21A is disposed along the inner peripheral surface of the cylindrical partition member 22A. Each of the coaxial power supply coil 17A and the coaxial catalyst coil 21A is formed as a helical shaped coaxial coil. The power supply coil 17 and the coaxial catalyst coil 21A are arranged coaxially along a central axis (not shown) that is set to extend in the vertical direction.

In the radical supply unit 91, the inner space of the cylindrical partition member 22A serves as a channel through which the processing gas supplied to the upper surface side of the ceiling plate 221 flows toward the radical supply space 5C disposed thereunder. Since the coaxial catalyst coil 21A is disposed in the channel, the inner space of the cylindrical partition member 22A also functions as the radical generation space 5B where radicals of the processing gas are generated. In each radical generation space 5B, a frame body part 35, which is a cylindrical frame member, is disposed along the outer periphery of the wire of the coaxial catalyst coil 21A.

In the frame body part 35, a plurality of protrusions 351 for supporting the coaxial catalyst coil 21A are scattered in the winding direction of the coaxial catalyst coil 21A. In the radical supply unit 91 configured as described above, the frame body part 35 serves as the catalyst placing table on which the coaxial catalyst coil 21A is placed. Further, the plurality of protrusions 351 disposed at the frame body part 35 also function as regulation members that regulates the coaxial catalyst coil 21A from extending in the axial direction when heated and displacing from the position facing the coaxial power supply coil 17A.

### Third Embodiment

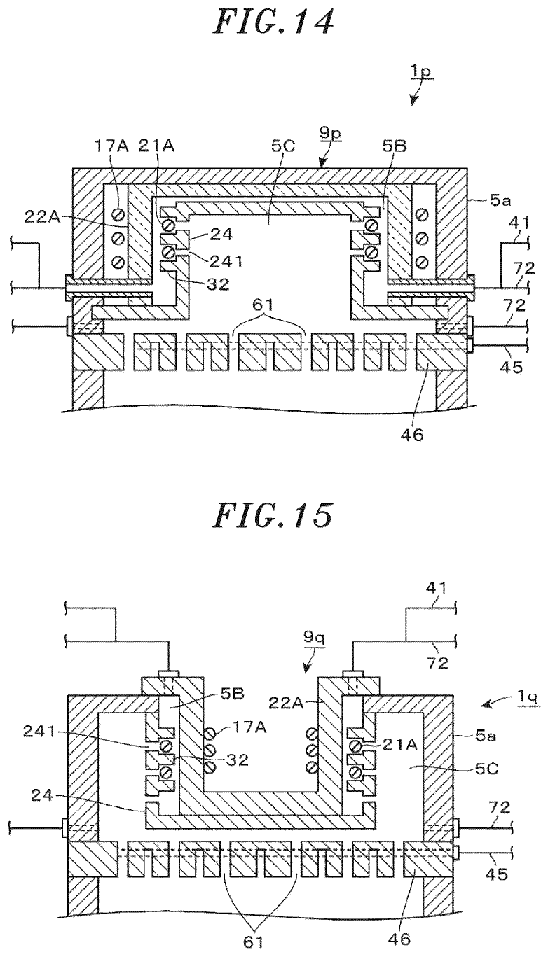

FIG. 14 shows an enlarged longitudinal side view of a radical processing apparatus 1p including a radical supply mechanism 9p according to a third embodiment. Compared to the radical supply mechanism 90 according to the second embodiment, which includes the plurality of radical supply units 91, a radical supply mechanism 9p according to the third embodiment includes a set of large coaxial power supply coil 17A and coaxial catalyst coil 21A. Also in the present embodiment, the coaxial power supply coil 17A is disposed along the outer peripheral surface of the cylindrical partition member 22A, and the coaxial catalyst coil 21A is disposed along the inner peripheral surface of the cylindrical partition member 22A. Further, a cylindrical tubular member 24 is disposed at the inner side of the tubular partition member 22A, and the space between the tubular partition member 22A and the tubular member 24 corresponds to the radical generation space 5B of the present embodiment. The helical-shaped protruding wall portion 32 is formed on the outer peripheral wall surface of the tubular member 24 to protrude toward the direction in which the coaxial catalyst coil 21A is disposed and extend along the winding direction of the wire of the coaxial catalyst coil 21A. The protruding wall portion 32 serves as the catalyst placing table on which the coaxial catalyst coil 21A is placed. The protruding wall portion 32 also functions as a regulation member that regulates the coaxial catalyst coil 21A from extending in the axial direction when heated and displacing from the position facing the coaxial power supply coil 17A.

Further, a plurality of radical supply holes 241 are formed in the tubular member 24 to allow radicals to pass therethrough. Particularly, in the present embodiment, the plurality of radical supply holes 241 include holes formed in the cylindrical member 24 in the area where the coaxial catalyst coil 21A fitted between the helical shaped protruding wall portions 32 is disposed. The radical supply space 5C, which is a radical circulation space where the radicals flow in a direction along the wall surface of the cylindrical member 24, is formed on the outlet side of the radical supply hole 241. Further, the gas distribution plate 46 having the plurality of radical channels 61 is disposed at the downstream end of the flow of radicals in the radical supply space 5C (the flow of the above-described “radical mixed gas”).

FIG. 15 shows an enlarged longitudinal side view of a radical processing apparatus 1q including a radical supply mechanism 9q according to a fourth embodiment. Compared to the radical supply mechanism 9p according to the third embodiment, the radical supply mechanism 9q of the fourth embodiment has a configuration in which the coaxial power supply coil 17A is arranged along the inner peripheral surface of the cylindrical partition member 22A and the coaxial catalyst coil 21A is arranged along the outer peripheral surface of the cylindrical partition member 22A. Therefore, the cylindrical member 24 is disposed on the outer side of the cylindrical partition member 22A. Further, the helical-shaped protruding wall portion 32 is formed on the inner peripheral wall surface of the cylindrical member 24 to protrude in the direction in which the coaxial catalyst coil 21A is disposed and extend along the winding direction of the wire of the coaxial catalyst coil 21A.

### Fifth Embodiment

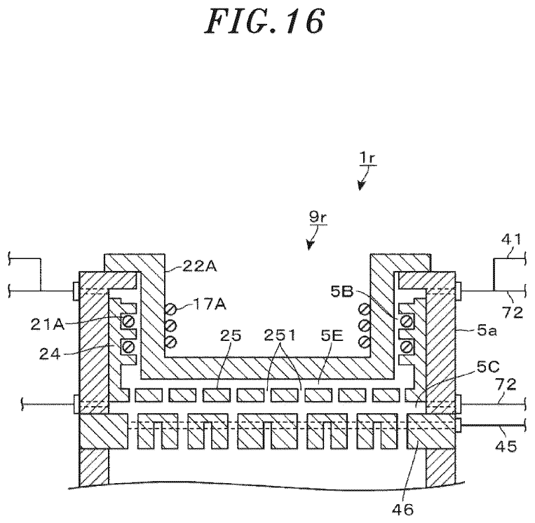

FIG. 16 shows an enlarged longitudinal side view of a radical processing apparatus 1r including a radical supply mechanism 9r according to a fifth embodiment. Compared with the radical supply mechanism 9q according to the fourth embodiment, the radical supply mechanism 9r according to the fifth embodiment has a configuration in which radicals (radical mixed gas) flowing in the radical generation space 5B are discharged toward the radical circulation space 5E disposed on the downstream end side of the radical generation space 5B. Therefore, the cylindrical member 24 of the present embodiment does not have the radical supply holes 241. The radical distribution plate 25 is disposed on the bottom surface of the radical circulation space 5E, and the radical mixed gas flows into the radical supply space 5C through the plurality of radical supply holes 251 formed in the radical distribution plate 25.

Also in the radical supply mechanisms 90 to 9r according to the second to fifth embodiments described using FIGS. 12 to 16, the tubular coaxial catalyst coil 21A may be used based on the same concept as the examples described using FIGS. 7 to 9. Further, the coaxial catalyst coil 21A may be provided with the pin 212 to increase the area of the metal catalyst based on the same concept as the example described with reference to FIGS. 10 and 11.

Here, in each of the above-described embodiments, it is not necessary to provide the gas distribution plate 46. The radical mixed gas discharged from the radical generation space 5B may be directly supplied to the processing space 5D. In this case, the raw material gas may be supplied from a nozzle inserted into the processing space 5D, for example.

Further, in the above-described embodiment, the case in which the partition member 22 is made of a dielectric material such as quartz or the like has been described. However, the partition member 22 is not limited thereto, and may contain a non-magnetic conductive metal such as aluminum or the like. Further, when the partition member 22 contains a metal, a dielectric film or a dielectric cover may be disposed on the surface of the partition member 22 that faces the radical generation space 5B in order to improve plasma resistance. The dielectric film may be an anodically oxidized film or a thermal sprayed ceramic film. Further, the dielectric cover may be a quartz cover or a ceramic cover.

In each of the above-described embodiments, the protruding wall portion 32 has a spiral shape extending parallel to the winding direction of the catalyst coil 21, and the catalyst coil 21 is disposed in a spiral-shaped recess surrounded by the support surface 31 and the inner surface 32a and the outer surface 32b of the protruding wall portion 32. However, the protruding wall portion 32 is not necessarily extend along the winding direction of the catalyst coil 21. For example, short protruding wall portions 32 may be intermittently arranged along the winding direction of the wire of the catalyst coil 21. If such protruding wall portions 32 are arranged along at least the outermost circumference of the wire of the catalyst coil 21, the displacement of the entire catalyst coil 21 due to temperature changes may be suppressed. Further, by increasing the number of protruding wall portions 32 arranged along the winding direction of the catalyst coil 21, the displacement can be effectively suppressed.

In the above-described embodiments, the example in which the substrate processing mechanism 11 forms a film on the substrate W by an ALD method for alternately supplying a raw material gas and radicals of a processing gas has been described. However, the film formation method is not limited thereto. For example, film formation may be performed by a chemical vapor deposition (CVD) method in which the radicals generated in the radical generation space 5B and the raw material gas may be continuously supplied and the gases react with each other in the processing space 5D. In addition, the film formed on the substrate W may react with the radicals of the processing gas to perform other types of processing, such as modification for modifying a film, and the like. Further, in the above-described embodiments, the example in which the radical processing apparatus 1 is integrated with the radical supply apparatus including the radical supply mechanism 9 has been described. However, the present disclosure is not limited thereto, and the radical supply mechanism 9 and the substrate processing mechanism 11 may be provided separately.

Further, the embodiments of the present disclosure are illustrative in all respects and are not restrictive. The above-described embodiments may be omitted, replaced, or changed in various forms without departing from the scope of the appended claims and the gist thereof.

1. A radical supply apparatus for supplying radicals of a processing gas for processing a substrate, comprising:
a housing divided into a radical generation space and a power supply space by a partition member configured to transmit electromagnetic waves;
a power supply coil provided in the power supply space, one end of which is connected to a high-frequency power supply and the other end of which is grounded or grounded via a capacitor;
a processing gas supply mechanism configured to supply the processing gas to the radical generation space;
a catalyst coil that is disposed in the radical generation space at a position facing the power supply coil and configured to act as a metal catalyst when heated by non-contact power supply from the power supply coil; and
a catalyst placing table disposed in the radical generation space, on which the catalyst coil is placed, and having a regulation member configured to regulate displacement of the catalyst coil, which is thermally expanded by heating, from the position facing the power supply coil,
wherein radicals of the processing gas are generated by contacting the processing gas with the heated catalyst coil, and are supplied to a space for processing the substrate.

2. The radical supply apparatus of claim 1, wherein the non-contact power supply to a wire of the catalyst coil is performed by electromagnetic resonance between the power supply coil and the catalyst coil.

3. The radical supply apparatus of claim 1, wherein the power supply coil and the catalyst coil are arranged parallel to each other and formed in a spiral planar shape,
the catalyst placing table is a support plate having a support surface that supports the catalyst coil, and
the regulating member is a spiral-shaped protruding wall portion that protrudes from the support surface and extends along a winding direction of the catalyst coil.

4. The radical supply apparatus of claim 3, wherein the support plate has a plurality of radical supply holes for supplying the radicals toward a space where the substrate is disposed.

5. The radical supply apparatus of claim 4, wherein the plurality of radical supply holes include holes formed in the support plate in an area where the catalyst coil fitted between the spiral-shaped protruding wall portions is disposed.

6. The radical supply apparatus of claim 1, wherein the power supply coil and the catalyst coil are arranged coaxially with each other, and wires thereof are arranged coaxially,
the catalyst placing table is a helical-shaped protruding wall portion that protrudes from a wall surface of a cylindrical member disposed on an inner or outer circumferential side of the catalyst coil toward a direction in which the catalyst coil is disposed and extends along a winding direction of the catalyst coil, and
the protruding wall portion functions as the regulation member.

7. The radical supply apparatus of claim 6, wherein the cylindrical member has a plurality of radical supply holes for allowing the radicals to pass therethrough, and
a radical circulation space through which the radicals flow in a direction along the wall surface of the cylindrical member is formed on an outlet side of the radical supply holes, and a gas distribution plate having a plurality of radical channels is disposed at a downstream end of the flow of the radicals in the radical circulation space.

8. The radical supply apparatus of claim 7, wherein the plurality of radical supply holes include holes formed in the cylindrical member in an area where the catalyst coil fitted between the helical-shaped protruding wall portions is disposed.

9. The radical supply apparatus of claim 3, wherein a plurality of communication holes are formed in a side surface of the protruding wall portion.

10. The radical supply apparatus of claim 1, wherein the power supply coil and the catalyst coil are formed as helical-shaped coaxial coils that are arranged coaxially with each other,
the radical generation space is formed at an inner side of the partition member formed in a cylindrical shape,
the catalyst placing table is a frame body part disposed along the catalyst coil and having a plurality of protrusions scattered in the winding direction of the catalyst coil to support the catalyst coil, and
the plurality of protrusions function as the regulation member.

11. The radical supply apparatus of claim 1, wherein the catalyst coil is formed in a tube shape with a plurality of openings formed on a sidewall thereof,
the processing gas supply mechanism supplies the processing gas toward the inner space of the tubular catalyst coil, and
radicals of the processing gas are generated by contacting the processing gas with an inner wall surface of the catalyst coil in the inner space, or by contacting the processing gas that has not reacted and discharged from the inner space to the radical generation space through the openings with an outer wall surface of the catalyst coil.

12. The radical supply apparatus of claim 1, wherein a plurality of pins acting as metal catalysts are provided on an outer surface of the catalyst coil.

13. A radical processing apparatus comprising:
the radical supply apparatus described in claim 1; and
a processing chamber to which radicals are supplied from the radical generation space and including a processing space where a substrate placing table on which the substrate is placed is disposed,
wherein radicals of the processing gas generated by the radical supply apparatus are supplied to the processing space to process the substrate.

14. The radical processing apparatus of claim 13, further comprising:
a gas distribution plate that partitions the radical generation space and the processing space,
wherein the gas distribution plate has a plurality of radical channels that are connected to the radical generation space and have downstream ends distributed and opened to the processing space.

15. The radical processing apparatus of claim 13, further comprising:
a raw material gas supply mechanism configured to supply a raw material gas, which contains a film raw material that reacts with the radicals and forms a film on the substrate, to the processing space,
wherein the raw material gas is supplied to the processing space and reacts with the radicals to form a film on the substrate.

16. The radical processing apparatus of claim 15, further comprising:
a gas distribution plate disposed to partition the radical generation space from the processing space,
wherein the gas distribution plate has a plurality of radical channels connected to the radical generation space and having downstream ends opened to the processing space, and a raw material gas channel separated from the radical channels, having downstream ends opened to the processing space, and through which the raw material gas from the raw material gas supply mechanism flows.

17. A method for generating radicals of a processing gas for processing a substrate, comprising:
supplying a power from a high-frequency power supply to a power supply coil, which is disposed in a power supply space in a housing and having one end connected to the high-frequency power supply and the other end that is grounded or grounded via a capacitor, and supplying a power in a non-contact manner to a catalyst coil disposed in a radical generation space facing the power supply space via a partition member in the housing to heat the catalyst coil;
supplying the processing gas from a processing gas supply mechanism to the radical generation space, and generating the radicals by contacting the processing gas with the catalyst coil that acts as a metal catalyst when heated; and
regulating displacement of the catalyst coil, which is thermally expanded by heating, from a position facing the power supply coil by using a regulation member of a catalyst placing table disposed in the radical generation space, wherein the catalyst coil is placed on the catalyst placing table.

18. A method for processing a substrate using radicals of a processing gas, comprising:
placing the substrate on a substrate placing table in a processing space in a processing chamber; and
supplying radicals of the processing gas generated by the method for generating radicals described in claim 17 to the processing space to process the substrate.
